(19) United States
(12) Patent Application Publication
(10) Pub. No.: US 2022/0084854 A1
(43) Pub. Date: Mar. 17, 2022

(54) WAFER TRANSFERRING DEVICE

(71) Applicant: CHANGXIN MEMORY TECHNOLOGIES, INC., Hefei City (CN)

(72) Inventor: Rong FU, Hefei City (CN)

(73) Assignee: CHANGXIN MEMORY TECHNOLOGIES, INC., Hefei City (CN)

(21) Appl. No.: 17/451,528

(22) Filed: Oct. 20, 2021

Related U.S. Application Data
(63) Continuation of application No. PCT/CN2021/100186, filed on Jun. 15, 2021.

(30) Foreign Application Priority Data
Sep. 16, 2020 (CN) 202010973763.X

(51) Int. Cl. H01L 21/67; H01L 21/673; G01D 5/241; G08B 21/18

(52) U.S. Cl. CPC H01L 21/67265; G08B 21/182; G01D 5/2417; H01L 21/6732

(57) ABSTRACT

A wafer transferring device includes a first placement slot and a second placement slot of wafer slots having two electrically conductive polar plates to form capacitance, the first polar plate on which is being placed a wafer is of a shape-deformable material, the distance between the first polar plate and the second polar plate is decreased upon placement of a wafer onto the first polar plate, between the polar plates are connected a detection circuit and a power supply, variations in distance between the two polar plates will cause variations in capacitance values of the capacitance, and states of wafers being placed on the first placement slot and the second placement slot can be determined according to variations in the capacitance value to which the first placement slot corresponds and in the capacitance value to which the second placement slot corresponds.

### CROSS-REFERENCE TO RELATED APPLICATIONS

This is a continuation of International Patent Application No. PCT/CN2021/100186 filed on Jun. 15, 2021, which claims priority to Chinese Patent Application No. 202010973763.X filed on Sep. 16, 2020. The disclosures of the above-referenced applications are hereby incorporated by reference in their entirety.

### BACKGROUND

A wafer transferring device serves a very important function in the process of semiconductor fabrication. The wafer transferring device is configured to temporarily store wafers and to transfer wafers among various operation desks. The wafer transferring device can be a sealed container to maintain environmental stability and cleanness inside the device, and to effectively prevent the wafers from directly contacting outside environs.

### SUMMARY

The present disclosure relates generally to the technical field of semiconductor fabrication, and more specifically to a wafer transferring device.

The present disclosure provides a wafer transferring device capable of timely detecting the states of wafers when the wafers are loaded into the wafer transferring device, and taking corresponding measures in a timely manner when abnormalities occur to the states of the wafers.

According to one aspect of the present disclosure, there is provided a wafer transferring device that comprises a top plate and a base plate disposed opposite to the top plate, a first side plate and a second side plate located between the top plate and the base plate and disposed opposite to each other, plural wafer slots disposed between the top plate and the base plate and each including a first placement slot and a second placement slot, of which the first placement slot is disposed at a surface of the first side plate facing towards the second side plate, and the second placement slot is disposed at a surface of the second side plate facing towards the first side plate; each of the first placement slot and the second placement slot includes two polar plates disposed opposite to each other, the first polar plate and the second polar plate together form a capacitor, the first polar plate is embodied as a shape-deformable plate, and distance between the first polar plate and the second polar plate is decreased upon placement of a wafer onto the first polar plate; between the first polar plate and the second polar plate are connected a detection circuit and a power supply, which power supply is configured to supply voltage to the first polar plate and the second polar plate; the detection circuit is configured to detect a capacitance value to which the first placement slot corresponds and a capacitance value to which the second placement slot corresponds, and determines states of wafers being placed on the first placement slot and the second placement slot according to variations in the capacitance value to which the first placement slot corresponds and in the capacitance value to which the second placement slot corresponds.

### BRIEF DESCRIPTION OF THE DRAWINGS

The accompanying drawings here are incorporated into the description and constitute part of the description, illustrate embodiments in conformity with the present disclosure, and explain the principles of the present disclosure together with the description.

FIG. 1 is a diagram schematically illustrating the structure of the wafer transferring device provided by the embodiments of the present disclosure;

FIG. 2 is a diagram schematically illustrating the entire structure of the wafer slot;

FIG. 3 is a side view of a placement slot in amplification;

FIG. 4 is a diagram schematically illustrating the circuitry inside a placement slot; and

FIG. 5 is a diagram schematically illustrating the state of variation of a placement slot being pressed against by a wafer.

### REFERENCE NUMERALS

top plate: 11; base plate: 12; first side plate: 13; second side plate: 14; first placement slot: 15; second placement slot: 16; first polar plate: 151; second polar plate: 152; detection circuit: 153; power supply: 154; communication module: 155; switch: 156; wafer: 20.

Through the above accompanying drawings are illustrated the definite embodiments of the present disclosure, which will be described in greater detail below. These accompanying drawings and literal description are not meant to restrict, in any manner possible, the scope of the conception of the present disclosure, but are directed to explain the concepts of the present disclosure to persons skilled in the art with reference to specific embodiments.

### DETAILED DESCRIPTION

Exemplary embodiments will be described in detail below, and their illustrations are shown in the accompanying drawings. Where the following description involves accompanying drawings, unless otherwise explained, identical numerals in different drawings represent the same or similar essential elements. The following exemplary embodiments do not represent the entire embodiments corresponding to the present disclosure. To the contrary, they are merely examples of the device and method described in detail in the claims and corresponding to certain aspects of the present disclosure.

A front opening unified pod (FOUP) is a frequently used wafer transferring device, in which FOUP are disposed plural placement slots, in each of which is stored one wafer. In the state of the art, during the process in which a robot arm places wafers from an operation desk onto the wafer transferring device, stacking and oblique insertion of wafers might occur. By “stacking” it is meant that plural wafers are placed in one placement slot, and by “oblique insertion” is meant the circumstance in which one wafer occupies two placement slots. Stacking and oblique insertion tend to cause damage to wafers, affect the quality of wafers, and even possibly render wafers to be discarded.

Some embodiments of the present disclosure can address how to detect the states of wafers in a wafer transferring device to avoid damage of the wafers.

Embodiments of the present disclosure provide a wafer transferring device, the wafer transferring device has detecting function, a shape-deformable wafer slot is disposed, when a wafer is placed in the wafer slot, the shape of the wafer slot is changed due to pressing by the wafer, and variation occurs in the distance between the upper and lower polar plates of the wafer slot, so the capacitance value of the capacitor to which the wafer slot corresponds is caused to vary, and it is possible to determine the state of the wafer placed on the wafer slot according to the variation in the capacitance value to which the wafer slot corresponds, so that it is possible to timely find abnormal states of wafers in the wafer transferring device when the wafers are loaded into the wafer transferring device, and to take corresponding measures in a timely manner.

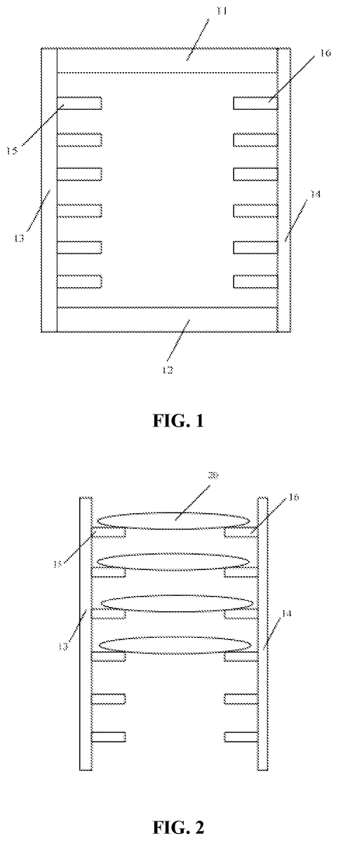

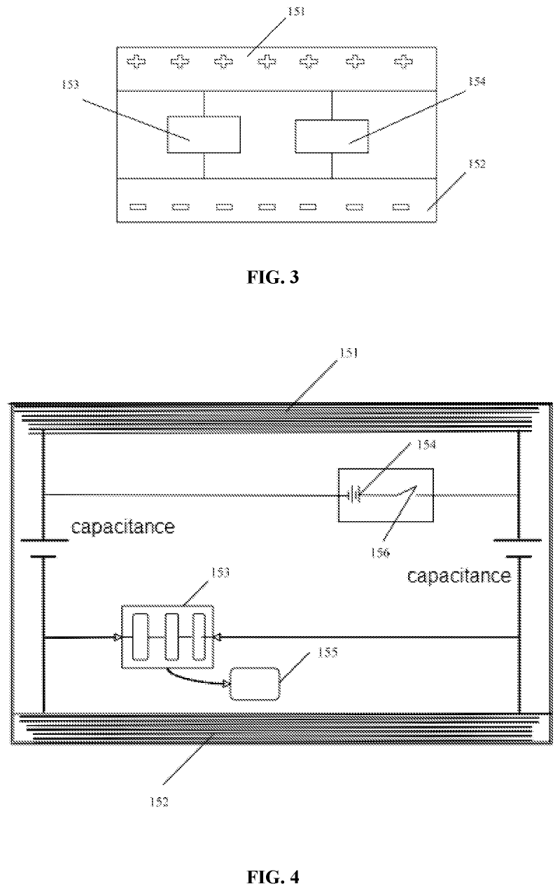

FIG. 1 is a diagram schematically illustrating the structure of the wafer transferring device provided by the embodiments of the present disclosure, FIG. 2 is a diagram schematically illustrating the entire structure of the wafer slot, FIG. 3 is a side view of a placement slot in amplification, and FIG. 4 is a diagram schematically illustrating the circuitry inside a placement slot. Referring to FIGS. 1-4, the wafer transferring device comprises a top plate 11 and a base plate 12 disposed opposite to the top plate 11, a first side plate 13 and a second side plate 14 located between the top plate 11 and the base plate 12 and disposed opposite to each other, and plural wafer slots disposed between the top plate 11 and the base plate 12; each wafer slot is used for placement of a wafer, and plural wafers 20 are sequentially placed, top to bottom, in placement slots; the top-to-bottom direction in the embodiments of the present disclosure means the direction from the top plate 11 to the base plate 12. The wafer transferring device further comprises a back plate and a front door (not shown) that can be opened, and the front door is opened during the wafer transferring process to place wafers in the wafer slot.

Each wafer slot includes a first placement slot 15 and a second placement slot 16, of which the first placement slot 15 is disposed at a surface of the first side plate 13 facing towards the second side plate 14, the second placement slot 16 is disposed at a surface of the second side plate 14 facing towards the first side plate 13, the first placement slot 15 and the second placement slot 16 are located on the same plane. The first placement slot 15 and the second placement slot 16 can be rectangular, semi-circular or elliptical, while the shapes of the first placement slot 15 and the second placement slot 16 are not defined in this embodiment.

At the surface of the first side plate 13 facing towards the second side plate 14 are disposed plural first placement slots 15, at the surface of the second side plate 14 facing towards the first side plate 13 are disposed plural second placement slots 16, the plural first placement slots 15 and plural second placement slots 16 are so disposed as to correspond to one another on a one-by-one basis.

Referring to FIG. 3, each of the first placement slot 15 and the second placement slot 16 includes two oppositely disposed first polar plate 151 and second polar plate 152, the first polar plate 151 and the second polar plate 152 together form a capacitor, and the polarities of voltages applied to the first polar plate 151 and the second polar plate 152 are reverse to each other, for instance, when the first polar plate 151 is applied with a positive voltage, the second polar plate 152 will be applied with a negative voltage; alternatively, when the first polar plate 151 is applied with a negative voltage, the second polar plate 152 will be applied with a positive voltage.

The first polar plate 151 is embodied as a shape-deformable plate, and the first polar plate 151 is a polar plate used for placement of a wafer 20; when the wafer 20 is placed onto the first polar plate 151, the shape of the first polar plate 151 is changed due to pressing by the wafer 20, and the distance between the first polar plate 151 and the second polar plate 152 is decreased, whereby the capacitance value of the capacitor is caused to vary. In this embodiment, the second polar plate 152 can be embodied either as a shape-deformable plate or not as a shape-deformable plate. The shape-deformable material used by the first polar plate 151 and the second polar plate 152 is not restricted in this embodiment.

In the embodiments of the present disclosure, the first placement slot 15 and the second placement slot 16 are equivalent to two parallel plate capacitors, whose capacitance formula is as follows:

$$C = \frac{Q}{{U}_{A\_} {U}_{B}} = \frac{{ɛ}_{r} S}{4 π k d}$$

Where εᵣ is relative dielectric constant, k is electrostatic constant, S is opposite area of two polar plates of the capacitor, d is distance between two polar plates of the capacitor, U_{A}−U_{B} is potential difference (namely voltage) between two polar plates of the capacitor.

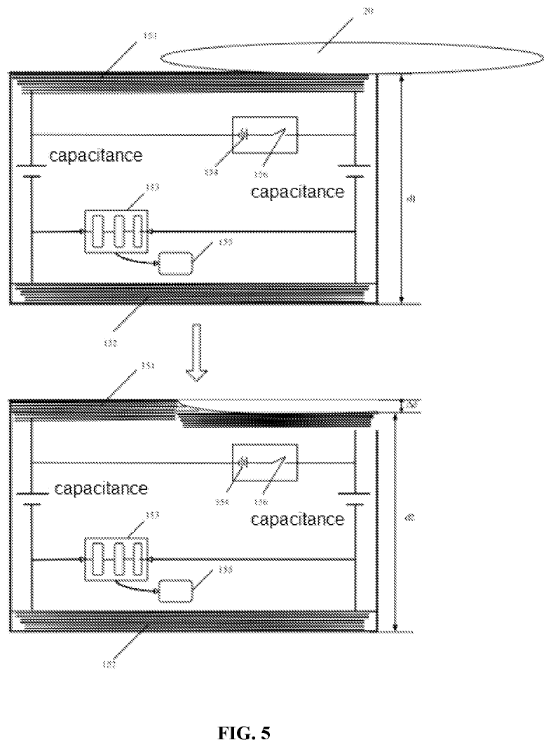

FIG. 5 is a diagram schematically illustrating the state of variation of a placement slot being pressed against by a wafer. Referring to FIG. 5, when no wafer 20 is placed on the first placement slot 15 and the second placement slot 16, the distance between two polar plates is a fixed value d1, at this time, the capacitance value to which the first placement slot 15 corresponds and the capacitance value to which the second placement slot 16 corresponds can be the same and single fixed value, and this fixed value can also be referred to as the initial capacitance value to which the first placement slot 15 corresponds and the initial capacitance value to which the second placement slot 16 corresponds.

When the wafer 20 is placed on the first placement slot 15 or the second placement slot 16, the shape of the first polar plate 151 of the first placement slot 15 or the second placement slot 16 is changed due to pressing, and this causes the distance between the first polar plate 151 and the second polar plate 152 to be decreased to d2, where d2 is smaller by Δd than d1.

As can be known from the foregoing capacitance computation formula of the capacitor, when the distance between two polar plates is decreased, the capacitance value of the parallel plate capacitor is increased.

Between the first polar plate 151 and the second polar plate 152 are connected a detection circuit 153 and a power supply 154, of which the power supply 154 is configured to supply voltage to the first polar plate 151 and the second polar plate 152. The detection circuit 153 is configured to detect a capacitance value to which the first placement slot 15 corresponds and a capacitance value to which the second placement slot 16 corresponds, and determines states of wafers being placed on the first placement slot 15 and the second placement slot 16 according to variations in the capacitance value to which the first placement slot 15 corresponds and in the capacitance value to which the second placement slot 16 corresponds.

The capacitance value to which the first placement slot 15 corresponds is the capacitance value of the capacitor formed by the two polar plates included in the first placement slot 15, and the capacitance value to which the second placement slot 16 corresponds is the capacitance value of the capacitor formed by the two polar plates included in the second placement slot 16.

The detection circuit 153 can detect the capacitance value to which the first placement slot 15 corresponds and the capacitance value to which the second placement slot 16 corresponds in real time or periodically, and compares the detected capacitance value to which the first placement slot 15 corresponds with the initial capacitance value to which the first placement slot 15 corresponds, wherein the initial capacitance value to which the first placement slot 15 corresponds can be stored in advance in the detection circuit 153. If the detected capacitance value to which the first placement slot 15 corresponds is different from the initial capacitance value to which the first placement slot 15 corresponds, it is then determined that variation occurs in the capacitance value to which the first placement slot 15 corresponds, and the state of the wafer is determined according to such variation; alternatively, the detection circuit 153 can further calculate a differential value of capacitance values according to the detected capacitance value to which the first placement slot 15 corresponds and the initial capacitance value to which the first placement slot 15 corresponds, and determine the state of the wafer according to the differential value of the capacitance values.

Optionally, the detection circuit 153 can also compare the capacitance value to which the first placement slot 15 corresponds as detected at the current time with the capacitance value to which the first placement slot 15 corresponds as detected at the previous time, to thereby determine the variation in the capacitance value to which the first placement slot 15 corresponds.

Optionally, the detection circuit 153 can also compare the average capacitance value to which the first placement slot 15 corresponds in the current detection period with the average capacitance value to which the first placement slot 15 corresponds in the previous detection period, to thereby determine the variation in the capacitance value to which the first placement slot 15 corresponds.

Exemplarily, states of wafers 20 include the circumstance as to whether the wafers 20 are placed on the placement slots, or whether the wafers 20 are stacked, or whether the wafers 20 are obliquely inserted. By means of the wafer transferring device in this embodiment, it is possible to timely find such abnormal states of wafers as to whether the wafers are obliquely inserted or stacked when the wafers are loaded into the wafer transferring device, to timely deal with the abnormal states of wafers, and to avoid damage of the wafers due to abnormal states of the wafers.

For instance, if it is not timely found when oblique insertion occurs in a wafer, collision might occur in the obliquely inserted wafer to thereby damage the wafer during the process in which the wafer transferring device transfers the wafer to the machine desk or other equipment, but by the wafer transferring device in this embodiment, it can be timely detected that oblique insertion occurs in a wafer during the wafer transferring process, and operating personnel can timely adjust the obliquely inserted wafer to avoid damage of the wafer.

Referring to FIG. 4, optionally, in the first placement slot 15 and the second placement slot 16 is further included a communication module 155, the communication module 155 is connected to the detection circuit 153, and the communication module 155 is configured to send states of wafers to monitor/control equipment. The monitor/control equipment is configured to display the states of wafers to a user, to facilitate the user to timely learn the states of wafers.

The communication module 155 and the monitor/control equipment can be communicating with each other either by a wired mode or a wireless mode, for instance, the communication module 155 and the monitor/control equipment can be communicating with each other by Wireless Fidelity (abbreviated as “WIFI”) technology or Bluetooth technology.

Optionally, the wafer transferring device further comprises a display screen connected with the detection circuit 153. After each detection circuit 153 acquires the state of a wafer, it sends the state of the wafer to the display screen, and the state of the wafer is displayed by the display screen.

Optionally, the wafer transferring device further comprises an alarm unit connected with the detection circuit 153 for outputting an alarm signal when states of the wafers indicate the occurrence of oblique insertion or stacking of the wafers. The alarm unit can include a light emitting diode (abbreviated as “LED”) and/or a buzzer, of which the LED informs operating personnel of abnormality occurring in the state of a wafer through flashing of its light, and the buzzer sends out specific sound signals to inform the operation personnel of the same.

Referring to FIG. 4, optionally, the power supply 154 is further connected with a switch 156 that controls on/off of the power supply 154.

At present, it is common to employ a robot arm to load wafers into the wafer slot of a wafer transferring device, and such loading is sequentially done from top to bottom under general circumstances. When the robot arm places wafers 20 onto the wafer slot, the distance between the two polar plates of the first placement slot 15 and the second placement slot 16 is decreased due to shape deform of the polar plates, and such decrease in distance between the two polar plates renders the capacitance value to which the first placement slot 15 corresponds and the capacitance value to which the second placement slot 16 corresponds to be increased. Upon detecting that the capacitance value to which the first placement slot 15 corresponds is increased, the detection circuit 153 determines that there is a wafer being placed in the first placement slot 15; upon detecting that the capacitance value to which the second placement slot 16 corresponds is increased, the detection circuit 153 determines that there is a wafer being placed in the second placement slot 16. It is possible, through such mode, to detect whether there are wafers in each of the wafer slots.

By the same token, when the wafer in the wafer slot is taken away, the deformed polar plates of the first placement slot 15 and the second placement slot 16 are restored to their original shapes, and the distance between the two polar plates is increased, while the increase in distance between the two polar plates renders the capacitance value to which the first placement slot 15 corresponds and the capacitance value to which the second placement slot 16 corresponds to be decreased. Upon detecting that the capacitance value to which the first placement slot 15 corresponds is decreased, the detection circuit 153 determines that the wafer placed in the first placement slot 15 has been taken away; upon detecting that the capacitance value to which the second placement slot 16 corresponds is decreased, the detection circuit 153 determines that the wafer placed in the second placement slot 16 has been taken away.

Under normal circumstance, wafers should be placed in the first placement slot 15 and the second placement slot 16 of the same wafer slot, and the capacitance values to which the first placement slot 15 and the second placement slot 16 of the wafer slot correspond will both be increased; understandably, due to deviation of the position 14 where wafers are placed, the increasing magnitudes of the capacitance values to which the first placement slot 15 and the second placement slot 16 correspond might be slightly deviated. If a wafer is obliquely inserted, for instance, one end of the wafer is placed in the first placement slot 15 of a first wafer slot and another end of the wafer is placed in the second placement slot 16 of a second wafer slot, and the first wafer slot and the second wafer slot are two adjacent wafer slots, it is then possible to base on the variations in capacitance values to which the two placement slots of the first wafer slot correspond to determine whether oblique insertion occurs in the wafer, and it is also possible to base on the variations in capacitance values to which the two placement slots of the second wafer slot correspond to determine whether oblique insertion occurs in the wafer.

Taking the first wafer slot for example, when the capacitance value to which the first placement slot 15 or the second placement slot 16 in the first wafer slot corresponds is increased, while no variation occurs in the capacitance value to which the other placement slot corresponds, it is determined that a wafer in the first wafer slot is obliquely inserted. When the capacitance values to which the first placement slot 15 and the second placement slot 16 in the first wafer slot correspond are both increased, it is determined that no wafer is obliquely inserted in the first wafer slot.

By “stacking” it is meant that two or more wafers are placed in one wafer slot; under normal circumstance, in one wafer slot can be placed only one wafer, and “stacking” means that two or more wafers are placed on the first placement slot 15 and the second placement slot 16 disposed opposite to each other. When the number of wafers placed in the wafer slot is increased, shape deformation of the first placement slot 15 and the second placement slot 16 of the wafer slot becomes larger, and the distance between the two polar plates of the first placement slot 15 and the second placement slot 16 becomes smaller, correspondingly, the capacitance values to which the first placement slot 15 and the second placement slot 16 correspond are also increased. For instance, when one wafer is placed in the wafer slot, shape deformation of the first placement slot 15 is 1 millimeter, that is to say, the distance between the two polar plates is decreased by 1 millimeter, and the capacitance value to which the first placement slot 15 corresponds is increased by 1 farad (F); when two wafers are placed in the wafer slot, shape deformation of the first placement slot 15 is 1.5 millimeter, that is to say, the distance between the two polar plates is decreased by 1.5 millimeter, and the capacitance value to which the first placement slot 15 corresponds is increased by 1.3 farad. Accordingly, it is possible to base on the increasing magnitudes of the capacitance values to which the first placement slot 15 and the second placement slot 16 in the wafer slot correspond to determine whether stacking occurs to the wafers placed in the wafer slot.

Specifically, when the detection circuit 153 detects that the capacitance values to which the first placement slot 15 and the second placement slot 16 in the wafer slot correspond are both increased, to a magnitude that is greater than a first threshold value, it is determined that stacking occurs to the wafers placed in the wafer slot.

In the aforementioned mode, the detection circuit 153 bases on the magnitudes of variation in the capacitance values to which the first placement slot 15 and the second placement slot 16 in the wafer slot correspond to determine whether stacking occurs to the wafers. Optionally, the detection circuit 153 can also base on the capacitance values to which the first placement slot 15 and the second placement slot 16 in the wafer slot correspond to determine whether stacking occurs to the wafers—when the detection circuit 153 detects that the capacitance values to which the first placement slot 15 and the second placement slot 16 in the wafer slot correspond are both increased, and that the capacitance values to which the first placement slot 15 and the second placement slot 16 correspond are both greater than a second threshold value, it is determined that stacking occurs to the wafers placed in the wafer slot.

In the wafer transferring device provided by the embodiments of the present disclosure, a first placement slot and a second placement slot of the wafer slot make use of two electrically conductive polar plates to form capacitance, the first polar plate on which is being placed a wafer is of a shape-deformable material, the distance between the first polar plate and the second polar plate is decreased upon placement of a wafer onto the first polar plate, between the polar plates are connected a detection circuit and a power supply, of which the power supply is configured to supply voltage to the polar plates, and the detection circuit is configured to detect the capacitance value to which the first placement slot corresponds and the capacitance value to which the second placement slot corresponds, variations in distance between the two polar plates will cause variations in capacitance values of the capacitance, so that states of wafers being placed on the first placement slot and the second placement slot can be determined according to variations in the capacitance value to which the first placement slot corresponds and in the capacitance value to which the second placement slot corresponds, whereby the wafer transferring device is enabled to timely find abnormal states of wafers when the wafers are loaded into the wafer transferring device, and to take corresponding measures in a timely manner.

After considering the description and practicing the disclosure made public here, persons skilled in the art would find it easy to conceive of other embodiment solutions of the present disclosure. The present disclosure is meant to cover any modifications, purpose of use or adaptable modifications of the present disclosure, and these modifications, purpose of use or adaptable modifications abide by the general principles of the present disclosure and include common knowledge or conventionally employed technical means in this field of specialty not made public by the present disclosure. The description and the embodiments are merely exemplary in nature, and the authentic scope and spirit of the present disclosure are pointed out by the claims that follow.

As should be understood, the present disclosure is not to be restricted by the precise structure described above and illustrated in the drawings, and could be variously amended and modified without departing from its scope. The scope of the present disclosure is merely defined by the attached claims.

What is claimed is:

1. A wafer transferring device, comprising: a top plate and a base plate disposed opposite to the top plate, a first side plate and a second side plate located between the top plate and the base plate and disposed opposite to each other, plural wafer slots disposed between the top plate and the base plate and each including a first placement slot and a second placement slot, of which the first placement slot is disposed at a surface of the first side plate facing towards the second side plate, and the second placement slot is disposed at a surface of the second side plate facing towards the first side plate; wherein
each of the first placement slot and the second placement slot includes two polar plates disposed opposite to each other, the first polar plate and the second polar plate together form a capacitor, the first polar plate is embodied as a shape-deformable plate, and distance between the first polar plate and the second polar plate is decreased upon placement of a wafer onto the first polar plate;
between the first polar plate and the second polar plate are connected a detection circuit and a power supply, which power supply is configured to supply voltage to the first polar plate and the second polar plate;
the detection circuit is configured to detect a capacitance value to which the first placement slot corresponds and a capacitance value to which the second placement slot corresponds, and determines states of wafers being placed on the first placement slot and the second placement slot according to variations in the capacitance value to which the first placement slot corresponds and in the capacitance value to which the second placement slot corresponds.

2. The wafer transferring device according to claim 1, wherein the detection circuit is further configured to determine that a wafer is being placed in the first placement slot when the capacitance value to which the first placement slot corresponds is increased, or to determine that a wafer is being placed in the second placement slot when the capacitance value to which the second placement slot corresponds is increased.

3. The wafer transferring device according to claim 1, wherein the detection circuit is further configured to determine that the wafer placed in the first placement slot has been taken away when the capacitance value to which the first placement slot corresponds is decreased, or to determine that the wafer placed in the second placement slot has been taken away when the capacitance value to which the second placement slot corresponds is decreased.

4. The wafer transferring device according to claim 1, wherein the detection circuit is further configured to determine that oblique insertion occurs to the wafer in the wafer slot when the capacitance value to which the first placement slot or the second placement slot corresponds is increased, while no variation occurs in the capacitance value to which the other placement slot corresponds.

5. The wafer transferring device according to claim 1, wherein the detection circuit is further configured to determine that stacking occurs to the wafers placed in the wafer slot when the capacitance values to which the first placement slot and the second placement slot correspond are both increased, to a magnitude that is greater than a first threshold value.

6. The wafer transferring device according to claim 1, wherein the second polar plate is embodied as a shape-deformable plate.

7. The wafer transferring device according to claim 2, wherein the second polar plate is embodied as a shape-deformable plate.

8. The wafer transferring device according to claim 3, wherein the second polar plate is embodied as a shape-deformable plate.

9. The wafer transferring device according to claim 4, wherein the second polar plate is embodied as a shape-deformable plate.

10. The wafer transferring device according to claim 5, wherein the second polar plate is embodied as a shape-deformable plate.

11. The wafer transferring device according to claim 1, wherein the detection circuit is further connected with a communication module for sending states of the wafers to monitor/control equipment.

12. The wafer transferring device according to claim 2, wherein the detection circuit is further connected with a communication module for sending states of the wafers to monitor/control equipment.

13. The wafer transferring device according to claim 3, wherein the detection circuit is further connected with a communication module for sending states of the wafers to monitor/control equipment.

14. The wafer transferring device according to claim 4, wherein the detection circuit is further connected with a communication module for sending states of the wafers to monitor/control equipment.

15. The wafer transferring device according to claim 5, wherein the detection circuit is further connected with a communication module for sending states of the wafers to monitor/control equipment.

16. The wafer transferring device according to claim 11, wherein the power supply is further connected with a switch that controls on/off of the power supply.

17. The wafer transferring device according to claim 1, further comprising a display screen connected with the detection circuit for displaying states of the wafers.

18. The wafer transferring device according to claim 2, further comprising a display screen connected with the detection circuit for displaying states of the wafers.

19. The wafer transferring device according to claim 3, further comprising a display screen connected with the detection circuit for displaying states of the wafers.

20. The wafer transferring device according to claim 1, further comprising an alarm unit connected with the detection circuit for outputting an alarm signal when states of the wafers indicate the occurrence of stacking or oblique insertion of the wafers.
